(19) United States
(12) Patent Application Publication
(10) Pub. No.: US 2003/0024467 A1
(43) Pub. Date: Feb. 6, 2003

(54) Method of eliminating near-surface bubbles in quartz crucibles

(75) Inventors: Richard J. Phillips, St. Peters, MO (US); Steven J. Keltner, Tega Cay, SC (US); John D. Holder, Lake St. Louis, MO (US)

Correspondence Address: SENNIGER POWERS LEAVITT AND ROEDEL, ONE METROPOLITAN SQUARE, 16TH FLOOR, ST LOUIS, MO, 63102, US

(73) Assignee: MEMC Electronic Materials, Inc.

(21) Appl. No.: 10/210,933

(22) Filed: Aug. 2, 2002

Related U.S. Application Data
(60) Provisional application No. 60/309,645, filed on Aug. 2, 2001.

(51) Int. Cl. C30B 15/00; C30B 21/06; C30B 27/02; C30B 28/10; C30B 30/04

(52) U.S. Cl. 117/20

(57) ABSTRACT

A method for reducing the concentration of near-surface bubbles in a quartz crucible suitable for growing monocrystalline silicon ingots by the Czochralski method is provided. The method comprises etching the inner surface of the crucible, preferably with an acidic solution, to substantially eliminate or reduce the concentration of near-surface bubbles from the inner surface of the crucible.

### CROSS-REFERENCE TO RELATED APPLICATIONS

This application claims the benefit of U.S. Provisional Application Serial No. 60/309,645, filed Aug. 2, 2001. The entire text of U.S. Provisional Application Serial No. 60/309,645 is hereby incorporated herein by reference.

### BACKGROUND OF THE INVENTION

The present invention generally relates to the production of semiconductor grade material. More specifically, the present invention is directed to a method for reducing the concentration of near-surface bubbles in quartz crucibles used in the preparation of single crystal silicon.

Single crystal silicon, which is the starting material for most semiconductor electronic component fabrication, is commonly prepared by the so-called Czochralski (“Cz”) method. Using the Cz method, the growth of the crystal is most commonly carried out in a crystal pulling furnace, wherein polycrystalline silicon (“polysilicon”) is charged to a crucible and melted by a heater surrounding the outer surface of the crucible side wall. A seed crystal is brought into contact with the molten silicon and a single crystal ingot is grown by extraction via a crystal puller. After formation of a neck is complete, the diameter of the crystal ingot is enlarged by decreasing the pulling rate and/or the melt temperature until the desired or target diameter is reached. The cylindrical main body of the crystal which has a generally constant diameter is then grown by controlling the pull rate and the melt temperature while compensating for the decreasing melt level. Near the end of the growth process, the crystal diameter must be reduced gradually to form an end-cone. Typically, the end-cone is formed by increasing the pull rate and heat supplied to the crucible. When the diameter becomes small enough, the ingot is then separated from the melt.

Crucibles used in conventional crystal pullers are commonly constructed of quartz because of its purity, temperature stability and chemical resistance. The side walls of conventional crucibles are substantially “opaque,” or more accurately “translucent,” throughout their thickness as a result of having a high density of bubbles therein. These bubbles are grown into the crucible wall as a result of conventional manufacturing processes in which quartz particles are heated and fused together in a relatively short time period (otherwise commonly referred to as arc fusing). For example, conventional translucent quartz crucibles are typically produced by a process in which quartz powder is introduced into a mold to form a layer along the inner surface of the mold. The quartz powder is then heated and fused together at the inner surface thereof while the mold is rotated to produce a quartz crucible.

Translucent quartz crucibles are widely utilized because they are strong and relatively easy to form in large sizes. However, such crucibles have a relatively high bubble content, i.e., a relatively high density of bubbles or pockets of gas contained in the crucible side wall near the radially outer half of the wall thickness. For example, conventional translucent quartz crucibles typically contain approximately 70,000 bubbles/cm³ with the bubbles ranging from about 50-200 microns in diameter, and the average bubble having a diameter of about 100 microns.

Quartz crucibles having a high bubble content are not without drawbacks. Prolonged exposure, e.g., up to 100 hours or more, of the inner surface of the crucible side wall to the high temperature silicon melt contained therein during crystal growth results in reaction of the silicon melt with the quartz crucible and leads to dissolution of the inner surface of the crucible side wall. This dissolution of the inner surface exposes bubbles in the crucible side wall to the molten silicon. As a result, the bubbles rupture, releasing gases from inside the bubbles and quartz particulate from the crucible side wall into the melt. Particulate in the melt can come into contact with the growing crystal at the melt interface and be incorporated into the crystal structure. When this happens, a resulting loss of zero dislocation structure in the crystal can occur which will lead to a decreased throughput of acceptable crystalline ingots.

One measurement of the loss of throughput associated with the use of quartz crucibles is the percentage of wafers manufactured from a crystal ingot which have at least one Large Light Point Defect (LLPD). A Light Point Defect is a light scattering event off of a polished silicon wafer surface which can be registered by an inspection tool and is the result of a localized topographical deviation from the nominally planar silicon surface. In other words, the Light Point Defect is the result of a particle or pit on the wafer surface that causes an increase in light scattering intensity relative to that of the surrounding wafer surface. Bubbles which cavitate from the crucible can become entrained in the melt and subsequently attach to the liquid/solid interface. This essentially results in a grown-in bubble (i.e. a crystal void defect) in the crystal. Consequently, when the crystal is sliced into wafers, the cut can progress through the void defect resulting in a pit on the wafer surface. Light Point Defects that have a large scattering potential, such as pits corresponding to a size of at least 10 microns or more in diameter, are classified as LLPDs.

To this end, it is conventional in the art to manufacture a translucent, multi-layer quartz crucible comprising an inner layer having a reduced bubble size and/or density and an outer layer having a relatively high bubble density. For example, U.S. Pat. No. 4,632,686 (Brown et al.) discloses a method of manufacturing quartz glass crucibles to have a “low bubble content.” This method comprises applying a vacuum pressure to the outer surface of the crucible during heating and fusion of the quartz powder. However, because the bubbles drawn from the inner layer of the crucible encounter substantial resistance in passing through the outer layer, the outer layer of the crucible has a relatively high density of bubbles of large size. An inspection of currently available crucibles manufactured according to this or similar applied vacuum processes reveals that the inner or “low bubble content” layer provided by such a method includes bubbles having an average size of about 150 microns and a bubble density of about 5000 bubbles/cm³.

U.S. Pat. No. 4,935,046 (Uchikawa et al.) discloses another multi-layer quartz glass crucible in which an outer, or base layer is translucent and an inner layer (e.g., 0.3 mm to 3.0 mm) is substantially transparent. The substantially transparent inner layer or “bubble-free zone” is said to have a low concentration of bubbles (e.g., about 10 bubbles per cm²) having a diameter between 20 microns and 50 microns and to be free of bubbles having a diameter greater than 50 microns. Thus, when the inner layer of the crucible is dissolved into the melt, particulate contamination of the melt resulting from ruptured bubbles is reduced.

However, conventional crucibles such as those disclosed above have had limited success in eliminating all crucible-related crystal defects. For example, it has been found that even in crucibles having a low bubble content inner layer as described by Uchikawa et al., small bubbles (otherwise known as “near-surface bubbles”) having a diameter of less than about 5 microns are present in the first 150 to 200 microns of the inside wall of the crucible. Thus, even in low-bubble content crucibles and crucibles with bubble-free zones, these near-surface bubbles can contribute to the formation of crystal defects as the inner surface of the crucible dissolves during extended exposure to the molten silicon.

### SUMMARY OF THE INVENTION

Among the several objects and features of the present invention, therefore, may be noted the provision of a crucible, and a method for the production thereof, wherein the concentration of bubbles near the inner surface of the crucible is substantially reduced; the provision of such a method which increases throughput of monocrystalline silicon ingots grown in a crystal puller equipped with a crucible of the present invention; and the provision of such a method which reduces the incidence of Large Light Point Defects in wafers manufactured from ingots grown in a crystal puller equipped with a crucible of the present invention.

Briefly, therefore, the present invention is directed to a method for reducing the concentration of bubbles near the inner surface of a quartz crucible. The method comprises etching the inner surface of the crucible, preferably with an acid solution.

The present invention is further directed to a crucible for use in growing monocrystalline silicon ingots in a crystal puller of the type used for growing monocrystalline silicon ingots according to the Czochralski method. The crucible comprises an inner surface having an average bubble concentration of less than about 50 bubbles per cm² as measured within the first 100 microns of the inner surface of the crucible. Preferably the crucible comprises an inner surface having an average bubble concentration of less than about 25 bubbles per cm² as measured within the first 100 microns of the inner surface of the crucible.

The present invention is further directed to a crucible for use in growing monocrystalline silicon ingots in a crystal puller of the type used for growing monocrystalline silicon ingots according to the Czochralski method, wherein the crucible comprises an inner surface having less than about 10 bubbles per cm² as measured in the straight wall of the crucible.

The present invention is further directed to a crucible for use in growing monocrystalline silicon ingots in a crystal puller of the type used for growing monocrystalline silicon ingots according to the Czochralski method, wherein the crucible comprises an inner surface having less than about 30 bubbles per cm² as measured in the corner radius of the crucible.

Still further, the present invention is directed to a process for growing monocrystalline silicon ingots in a crystal puller of the type used for growing monocrystalline silicon ingots according to the Czochralski method. The crystal puller is characterized as having a housing, a crucible in the housing for containing molten silicon and a pulling mechanism for pulling an ingot upward from the molten silicon. The process comprises contacting a seed crystal with molten silicon contained in the crucible, the inner surface of the crucible being characterized as having less than about 10 bubbles per cm² as measured in the straight wall of the crucible.

Other objects and features of the present invention will be in part apparent and in part pointed out hereinafter.

### BRIEF DESCRIPTION OF THE DRAWINGS

FIG. 1A depicts a photomicrograph of near-surface bubbles in a straight wall section of a conventional 22-inch fused quartz crucible.

FIG. 1B depicts a photomicrograph of near-surface bubbles in a bottom section of a conventional 22-inch fused quartz crucible.

FIG. 1C depicts a photomicrograph of near-surface bubbles in a corner radius of a conventional 22-inch fused quartz crucible.

FIG. 2A depicts a photomicrograph of near-surface bubbles in a straight wall section of a conventional 24-inch fused quartz crucible.

FIG. 2B depicts a photomicrograph of near-surface bubbles in a bottom section of a conventional 24-inch fused quartz crucible.

FIG. 2C depicts a photomicrograph of near-surface bubbles in a corner radius of a conventional 24-inch fused quartz crucible.

FIG. 3 is a graphical representation of the etching rate results of Example 1.

FIG. 4 depicts a photomicrograph of near-surface bubbles present in the conventional quartz crucible used in Example 3.

FIG. 5A depicts a photomicrograph of a view normal to the surface of the conventional quartz crucible used in Example 3 before etching.

FIG. 5B depicts a photomicrograph of a view normal to the surface of the quartz crucible used in Example 3 after etching the crucible surface.

### DETAILED DESCRIPTION OF THE PREFERRED EMBODIMENT

In accordance with the process of the present invention, it has been found that silicon crystal defects, particularly Large Light Point Defects (LLPDs) in silicon wafers sliced from silicon single crystals, can be significantly reduced by eliminating or substantially reducing the concentration of near-surface bubbles in the crucible from which the crystal is pulled. By exposing the inner surface of a quartz crucible to a controlled acid etch prior to silicon crystal growth, a pre-determined amount of the quartz surface can be removed to expose the near-surface bubbles, thereby opening the bubbles and releasing their contents prior to initiating the growth process. Releasing the contents of the near-surface bubbles prior to crystal growth essentially eliminates the near-surface bubbles and prevents the unwanted release of contaminants and/or particulate into the crystal melt during the growth process.

Near-surface bubbles are small bubbles present within the first about 150 to about 200 microns of the inner surface of conventional quartz crucibles. Typically, the near-surface bubbles have a diameter of less than about 5 microns (i.e., less than about 4, 3, 2, 1, or 0.5 microns). Applicants made the surprising discovery of near-surface bubbles while testing a conventional crucible in a vacuum furnace to simulate the thermal and vacuum environment of a crystal puller. This test, hereinafter referred to as a vacuum bake test, is designed to simulate the atmospheric conditions inside the crystal furnace during crystal growth while isolating the crucible from the influence of the graphite parts and silicon melt associated with the Cz crystal growth process. The vacuum bake test typically comprises heating a conventional quartz crucible either for a period of about 24 hours at a temperature of about 1600° C. or for a period of about 48 hours at a temperature of about 1500° C. in an argon atmosphere having a vacuum pressure of from about 2 to about 10 torr. Preferably, the vacuum bake test is conducted by heating a conventional quartz crucible for a period of about 48 hours at a temperature of about 1500° C. in a 2 torr argon atmosphere. Applicants have found that over the course of heating the crucible in the vacuum bake test, near-surface bubbles present in the crucible tend to enlarge and agglomerate. Without being held to a particular theory, it is believed that dissolved gases such as N₂ come out of solution during the heating and contribute to bubble growth. Thus, the near-surface bubbles, which are previously too small to be detected, become visible to the naked eye and can be quantified.

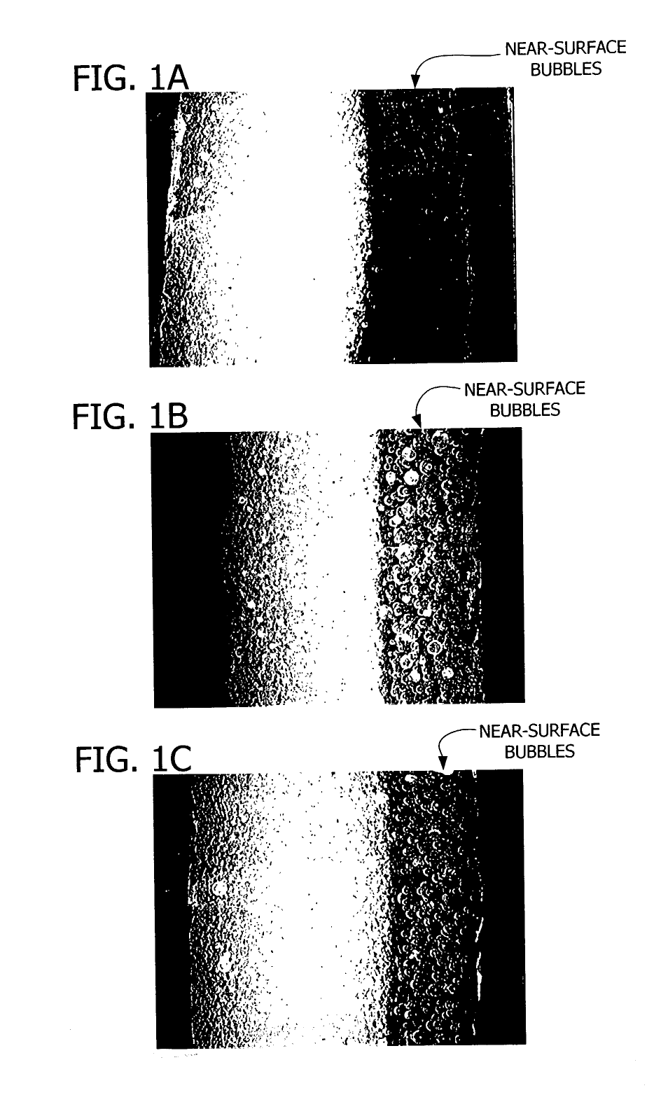

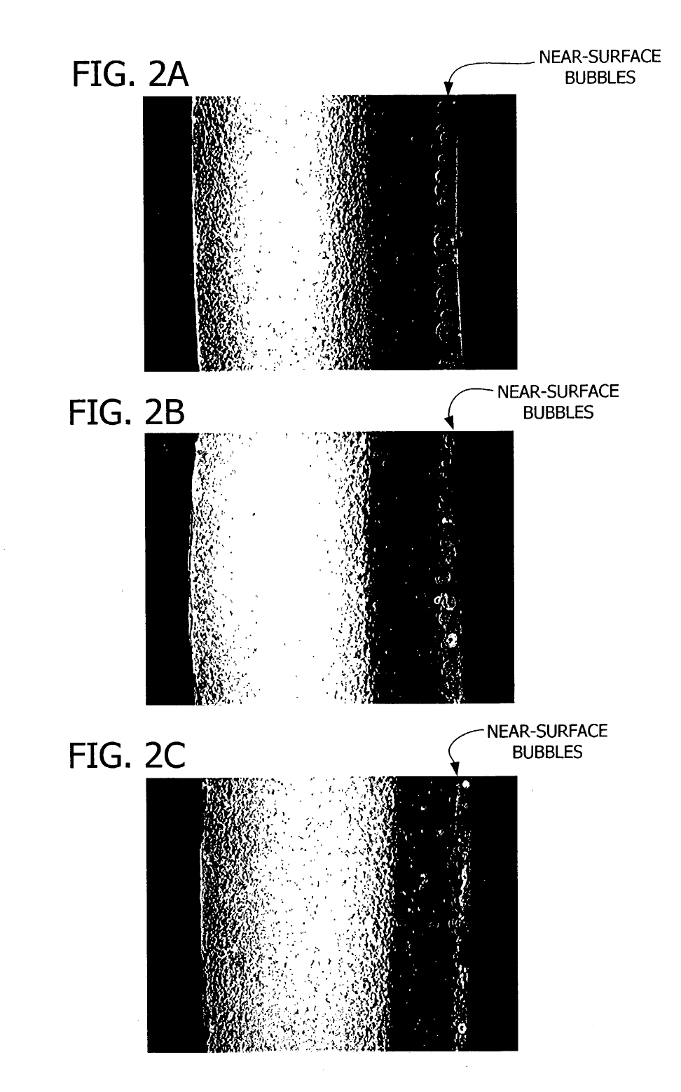

Experience to date suggests that near-surface bubbles are typically present within about 150 to 200 microns of the inner surface of conventional quartz crucibles in a concentration of about 150 to about 200 bubbles/cm² of as-fused crucible. For example, FIGS. 1A through 1C show the presence of near-surface bubbles in a conventional 22″ crucible after the completion of a vacuum bake test. In particular, FIG. 1A shows near-surface bubbles in a straight wall section of the crucible, FIG. 1B shows near-surface bubbles in the corner radius of the crucible and FIG. 1C shows near-surface bubbles in the bottom of the crucible. Likewise, FIGS. 2A through 2C show the presence of near-surface bubbles in a conventional 24″ crucible subjected to a vacuum bake test. As shown in FIGS. 1A through 1C and FIGS. 2A through 2C, near-surface bubbles have been found to be more prevalent in the corner radius areas of the crucible rather than the straight walls or the bottom of the crucible.

During the crystal growth process, the near-surface bubbles become exposed and rupture or burst as the inner surface of the crucible is eroded during prolonged exposure to the silicon melt. This bursting or rupture causes the contents of the near-surface bubbles to enter the crystal melt, which can result in bubbles becoming attached to the liquid/solid interface or further incorporated into the grown silicon crystal as a crystal void defect. Further, the rupture of near-surface bubbles during crystal growth can result in the separation of quartz particulate from the crucible surface. Such separated quartz particulate can become entrained in the melt, which often leads to crystal growth defects and the loss of zero dislocation crystal growth.

In the process of the present invention, near-surface bubbles are reduced and/or eliminated by etching the inner surface of the crucible. Typically, it is desired to etch the crucible surface such that the average concentration of near-surface bubbles is reduced to less than about 50 bubbles per cm² of crucible (i.e., less than about 25, 15, 10, 5 or 2 bubbles per cm² of crucible.) As stated above, near-surface bubbles have been found to be more prevalent in the corner radius areas of the crucible rather than the straight walls or the bottom of the crucible. Accordingly, the number of bubbles remaining after etching the surface of the crucible is lower in the straight wall and the bottom of the crucible than in the corner radius. Preferably, the method of the present invention reduces the number of near-surface bubbles such that, after etching, the inner surface of the crucible contains less than about 10 bubbles per cm² (i.e., less than about 8, 6, 4 or 2 bubbles per cm²) in the straight wall and bottom sections of the crucible and less than about 30 bubbles per cm² (i.e., less than about 25, 20, 15, 10 or 5 bubbles per cm²) in the corner radius of the crucible.

Thus, in one embodiment, the process generally comprises etching the crucible surface for a period of time sufficient to remove about 100 microns, preferably about 200 microns, and more preferably about 300 microns of quartz from the inside surface of the crucible. In a preferred embodiment, the inner surface of the crucible is etched by contacting the crucible with a solution comprising an acid. Any acid suitable for etching quartz may be used in the etching solution. For example, a preferred etching solution comprises hydrogen fluoride in a concentration of at least about 20% by weight. More preferably, the etching solution is a high purity, or semiconductor grade 49% Hydrogen Fluoride such as that commercially available from Sigma Aldrich Co., Milwaukee, Wis. Stronger acid solutions, such as 70% HF may be used; however, due to increased safety and handling concerns, such concentrations are not typically employed.

The etching solution may be contacted with the inner surface of the crucible in any manner known to the art for etching the crucible surface. For example, the crucible may be filled with etching solution such that the solution only contacts the inner surface of the crucible or the entire crucible may be submerged in etching solution such that both the inside and outside surfaces of the crucible contact the solution. In any case, it will be well within the ordinary skill in the art to optimize the method of the present invention such that the most cost effective means for contacting the inner surface of the crucible with etching solution is selected.

Typically, more concentrated etching solutions require less time to reduce or eliminate near-surface bubbles. For example, in an embodiment using a 49% HF acid etch, it has been found that contacting the inner surface of the crucible with the acid solution for a period of about 3 hours is sufficient to remove about 250 to about 300 microns of quartz. The process comprises contacting the inner surface of the crucible with the acid solution by, for example, filling the crucible with acid. After letting the filled crucible stand for the determined period of time, the acid is pumped out of the crucible and the crucible is rinsed and allowed to dry before being further processed or implemented in the crystal growth process.

It is important to note that the parameters for the method of the present invention may be other than herein described without departing from the scope of the present invention. Thus, it is within the ordinary skill in the art to refine and/or optimize the parameters such as acid concentration, etching duration, degree of etching, etc., for example, through empirical calculation. In such a case, it may be beneficial to determine the size and number of near-surface bubbles in a crucible prior to etching the crucible surface. Therefore, in another embodiment of the present invention, the near-surface bubbles are quantified by conducting a vacuum bake test as described above before etching the crucible surface.

It should be further noted that the method of the present invention can be applied to reduce or eliminate near-surface bubbles in any type of quartz crucible surface including, for example, conventional quartz crucibles or coated crucibles which have been treated to improve zero dislocation growth as described in U.S. Pat. Nos. 5,976,247 and 5,980,629, which are hereby incorporated herein by reference.

### EXAMPLES

The following examples set forth one approach that may be used to carry out the process of the present invention. Accordingly, these should not be interpreted in a limiting sense.

### Example 1

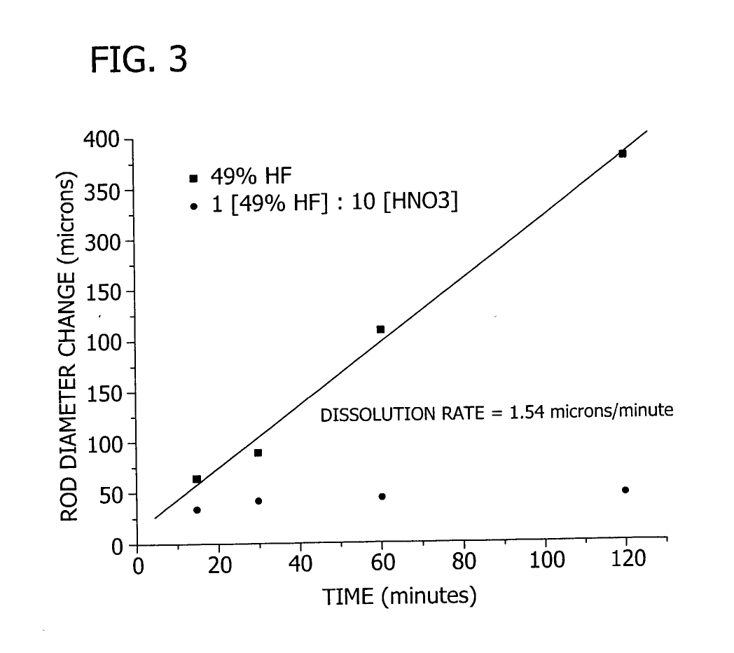

This example demonstrates the determination of etch rates for fused quartz similar to that used in conventional quartz crucibles. In the experiment, a machined rod of fused quartz was immersed in acid for various lengths of time. The observed change in the rod diameter was correlated to a dissolution or etch rate. The experiment was run twice, first using 49% hydrogen fluoride as the acid solution and second with an acid solution containing 49% hydrogen fluoride and nitric acid in a 1:10 molar ratio. The results of the two runs are shown graphically in FIG. 3.

As seen in the figure, etching with a solution comprising 49% hydrogen fluoride alone was successful with a dissolution rate of about 1.54 microns/min. The etching solution containing 49% hydrogen fluoride and nitric acid in a 1:10 molar ratio achieved little or no etching of the machined rod.

### Example 2

This example demonstrates a reduction in the number of bubbles near the surface of a crucible etched in accordance with the process of the present invention. The experiment was conducted by contacting the inner surface of a conventional quartz crucible with a solution containing 49% HF. The crucible was contacted with the acidic solution for a period of about 180 minutes to remove approximately 250 to 300 microns of quartz from the inside wall of the crucible.

The crucible was then subjected to a vacuum bake test along with a conventional quartz crucible that was not etched. The crucibles were heated to a temperature of 1500° C. for about 48 hours in an argon atmosphere at 2 torr. Near-surface bubbles were then quantified in each of the crucibles in the upper wall and the corner radius. Results of the vacuum bake test are shown in Table 1. The test results indicate that the etch was successful in reducing the number of near-surface bubbles. In the upper wall, there were few bubbles in either sample, with the etched crucible containing half as many bubbles as the conventional crucible. In the corner radius, near-surface bubbles were an order of magnitude less in the etched crucible than in the conventional crucible.

TABLE 1
Vacuum Bake Results for Example 2

| | |
|---|---|
| | Corner Radius Bubble |
| Upper Wall Bubble Data | Data |

| | avg. | | avg. | |
|---|---|---|---|---|
| | D | D | | |
| Sample | (μm) | No. per cm² | (μm) | No. per cm² |
| etched | 104 | 10 | 88 | 30 |
| not | 137 | 20 | 93 | 290 |
| etched | | | | |

### Example 3

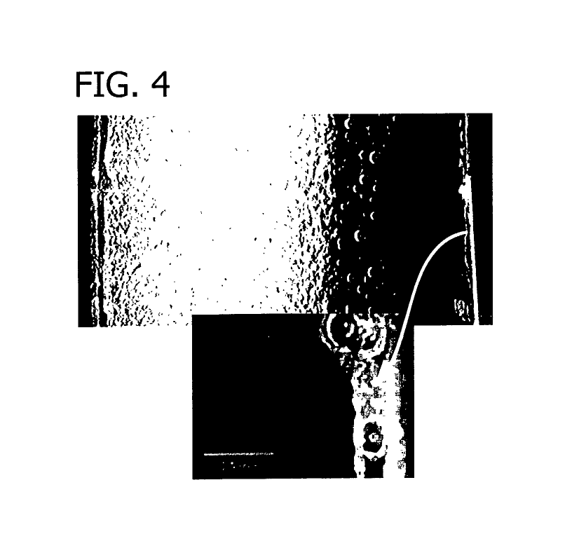

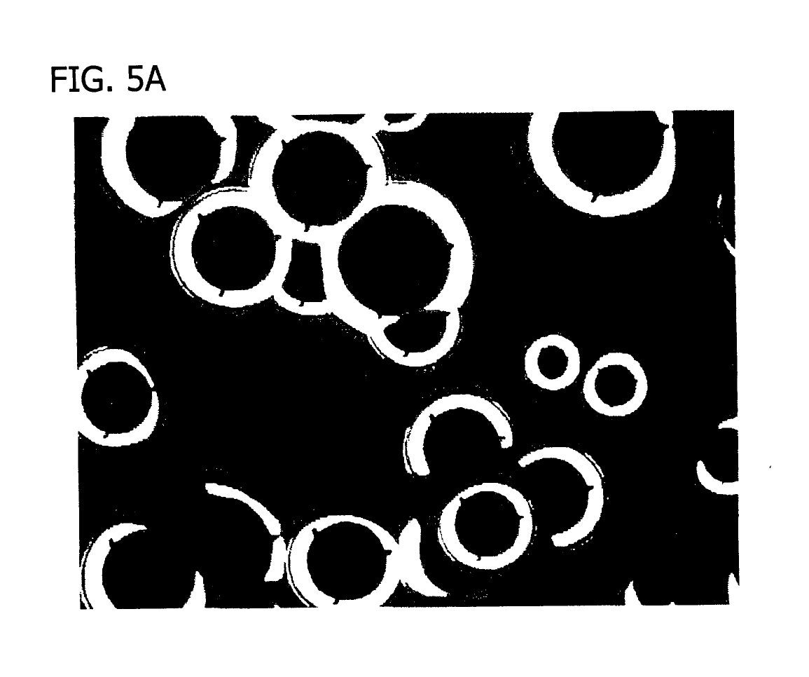

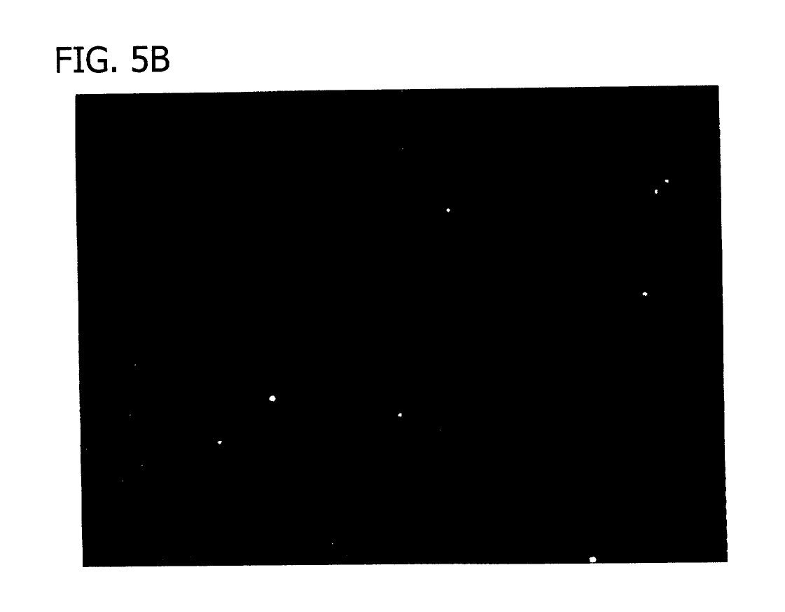

This example demonstrates the reduction in wafer defects achieved by growing single crystal silicon in an etched crucible. The experiment was conducted using two conventional quartz crucibles, both of which were Model 588 V3B commercially available from General Electric Co., Cleveland, Ohio. Each of the crucibles had near-surface bubbles as illustrated in FIG. 4. The crucibles were etched to remove approximately 300 to 400 microns of the inside surface by contacting the crucibles with an acidic etching solution containing hydrogen fluoride (49%) for a period of about 180 minutes. FIG. 4A is a photograph taken from a view normal to the surface of the first crucible before etching and FIG. 4B is a photograph normal to the surface of the first crucible after etching.

After etching, the crucibles were rinsed and dried and placed in separate crystal pulling furnaces for silicon crystal growth. Each of the crystal pulling furnaces comprised a classical open architecture hot zone for growing 22-inch diameter single crystal silicon ingots. The crucibles were charged with polysilicon and single crystal silicon growth was initiated. One crucible received an all chunk charge of polysilicon for crystal growth and the other received a mixed charge of polysilicon (granular fed onto a melting chunk).

Wafers from the grown crystals were inspected using a standard CR80 Laser Scanning technique for locating and counting surface particles and wafer pits. Typically, an average of 2.5% of wafers produced from an all chunk charge of polysilicon in a conventional quartz crucible would be expected to have one or more pit, and an average of 6.0% of wafers produced from a mixed charge of polysilicon in a conventional quartz crucible would be expected to have one or more pits on the wafer surface. However, the laser scanning results for the wafers produced from the etched crucibles in this example showed markedly improved results, with only 0.8% of wafers produced from the all chunk charge and 1.9% of wafers produced from the mixed charge having one or more pits on the wafer surface.

What is claimed:

1. A method for reducing the concentration of bubbles near the inner surface of a quartz crucible, the method comprising etching the inner surface of the crucible.

2. A method as set forth in claim 1 wherein the inner surface of the crucible is etched to open bubbles beneath the crucible surface.

3. A method as set forth in claim 1 wherein said etching removes at least about 10 microns of quartz from the crucible surface.

4. A method as set forth in claim 1 wherein said etching removes about 100 microns of quartz from the crucible surface.

5. A method as set forth in claim 1, wherein said etching removes about 200 microns of quartz from the crucible surface.

6. A method as set forth in claim 1, wherein said etching removes about 300 microns of quartz from said crucible surface.

7. A method as set forth in claim 1 wherein said crucible surface is etched by contacting the surface with a solution comprising an acid.

8. A method as set forth in claim 7 wherein said solution has an acid concentration of at least about 20% by weight.

9. A method as set forth in claim 7 wherein the crucible surface is contacted with said acidic solution for a period of time sufficient to remove at least about 100 microns of quartz from the crucible surface.

10. A method as set forth in claim 7, wherein the crucible surface is contacted with said acidic solution for a period of time sufficient to remove at least about 200 microns of quartz from the crucible surface.

11. A method as set forth in claim 7, wherein the crucible surface is contacted with said acidic solution for a period of time sufficient to remove at least about 300 microns of quartz from the crucible surface.

12. A method as set forth in claim 7 wherein said acid comprises hydrogen fluoride.

13. A method as set forth in claim 1 further comprising, prior to etching the inner surface of the crucible:
heating the crucible in a furnace to simulate the conditions in a crystal puller environment during crystal growth; and
determining the quantity and location of bubbles near the inner surface of the crucible.

14. A method as set forth in claim 13 wherein the crucible is heated to a temperature of about 1500° C. for a period of about 48 hours under a vacuum pressure of from about 2 to about 10 torr.

15. A method as set forth in claim 13 wherein the crucible is heated to temperature of about 1600° C. for a period of about 24 hours under a vacuum pressure of from about 2 to about 10 torr.

16. A method as set forth in claim 13, wherein said etching removes about 100 microns of quartz from the inner surface of the crucible.

17. A method as set forth in claim 13, wherein said etching removes about 200 microns of quartz from the inner surface of the crucible.

18. A method as set forth in claim 13, wherein said etching removes about 300 microns of quartz from the inner surface of the crucible.

19. A method as set forth in claim 13 wherein the crucible surface is etched with a solution comprising an acid.

20. A method as set forth in claim 19 wherein said acid comprises hydrogen fluoride.

21. A crucible for use in growing monocrystalline silicon ingots in a crystal puller of the type used for growing monocrystalline silicon ingots according to the Czochralski method, the crucible comprising an inner surface having an average bubble concentration of less than about 50 bubbles per cm² as measured within the first 100 microns of the inner surface of the crucible.

22. A crucible as set forth in claim 21, wherein the crucible comprises an inner surface having an average bubble concentration of less than about 25 bubbles per cm² as measured within the first 100 microns of the inner surface of the crucible.

23. A crucible as set forth in claim 21, wherein the crucible comprises an inner surface having less than about 10 bubbles per cm² as measured in the straight wall of the crucible.

24. A crucible as set forth in claim 21, wherein the crucible comprises an inner surface having less than about 30 bubbles per cm² as measured in the corner radius of the crucible.

25. A process for growing monocrystalline silicon ingots in a crystal puller of the type used for growing monocrystalline silicon ingots according to the Czochralski method, the crystal puller having a housing, a crucible in the housing for containing molten silicon and a pulling mechanism for pulling an ingot upward from the molten silicon, the process comprising:
contacting a seed crystal with molten silicon contained in said crucible, the inner surface of said crucible being characterized as having an average bubble concentration of less than about 50 bubbles per cm² as measured within the first 100 microns of the inner surface of the crucible.

26. A process as set forth in claim 25, wherein the inner surface of said crucible is characterized as having an average bubble concentration of less than about 25 bubbles per cm² as measured within the first 100 microns of the inner surface of the crucible.

27. A process as set forth in claim 25, wherein the inner surface of said crucible is characterized as having less than about 10 bubbles per cm² as measured in the straight wall of the crucible.
